(19) United States
(12) Patent Application Publication
(10) Pub. No.: US 2025/0056929 A1
(43) Pub. Date: Feb. 13, 2025

(54) LIGHT EMITTING DIODE, LIGHT EMITTING DEVICE, AND MANUFACTURING METHOD FOR LIGHT EMITTING DIODE

(71) Applicant: Tianjin Sanan Optoelectronics Co., Ltd., Tianjin (CN)

(72) Inventors: Nini ZHANG, Tianjin (CN); Jin WANG, Tianjin (CN)

(73) Assignee: Tianjin Sanan Optoelectronics Co., Ltd., Tianjin (CN)

(21) Appl. No.: 18/777,439

(22) Filed: Jul. 18, 2024

(30) Foreign Application Priority Data
Aug. 7, 2023 (CN) 202310984083.1

(51) Int. Cl. H01L 33/30; H01L 33/00; H01L 33/44

(52) U.S. Cl. CPC H01L 33/30; H01L 33/0062; H01L 33/44

(57) ABSTRACT

A light emitting diode, a light emitting device, and a manufacturing method for the light emitting diode are provided. The light emitting diode includes: a substrate having an upper surface and a lower surface opposite to each other; a semiconductor epitaxial stack including a first semiconductor layer, an active layer, and a second semiconductor layer stacked on the upper surface of the substrate; a transparent conductive layer disposed on an upper surface of the second semiconductor layer away from the substrate; a sidewall formed on edges of the semiconductor epitaxial stack and the substrate; and a passivation layer covering a surface of the transparent conductive layer and connected to the sidewall, wherein a portion of the sidewall not covered by the passivation layer has a roughened structure, and the roughened structure includes a protrusion.

### CROSS-REFERENCE TO RELATED APPLICATION

This application claims the priority benefit of China application serial no. 202310984083.1, filed on Aug. 7, 2023. The entirety of the above-mentioned patent application is hereby incorporated by reference herein and made a part of this specification.

### BACKGROUND

### Technical Field

The disclosure relates to the field of semiconductor manufacturing technology, and in particular to a light emitting diode, a light emitting device, and a manufacturing method for the light emitting diode.

### Description of Related Art

The light emitting diode (LED) has good optical properties such as low power consumption, high brightness, long life, high reliability, and small size, which has been widely used in lighting, screen display, backlight, and other fields. Further improving the luminous efficiency of LEDs is the current focus of the industry.

There are two main factors that affect the luminous efficiency of LEDs. One is the efficiency of converting electrons into photons, which is called the internal quantum efficiency (IQE); the other is the efficiency of photons generated by the active layer being emitted from the inside of the LED, which is called the external quantum efficiency (EQE). The two factors together determine the luminous efficiency of LEDs. Improving the internal quantum efficiency involves improving the quality of epitaxial growth and increasing the probability of electrons and holes combining. On the other hand, if the light generated by the LED cannot be effectively extracted, part of the light will be reflected or refracted back and forth inside the LED due to total internal reflection, and eventually absorbed by the electrode or the light emitting layer, which makes it impossible to increase the brightness. Therefore, the light emitting surface is usually roughened to improve the external quantum efficiency (EQE), thereby the luminous brightness and luminous efficiency of LED are improved.

The principle of surface roughening to improve the light emitting efficiency of LED is to use the grooving structure of the light emitting surface of the LED to scatter or guide the light at the total reflection angle out of the chip (or die), thereby the proportion of light that can be emitted to the outside of the LED is increased. Generally, the front side or the side surface of a light emitting diode may be roughened to improve the external quantum efficiency thereof. When roughening the surface and sidewalls of light emitting diodes, since the strong acid solution used causes certain damage to the transparent conductive layer and epitaxial layer on the front of the light emitting diode, a chemical deposition method (CVD) is generally used to deposit a silicon nitride layer on the front of the chip to protect the transparent conductive layer on the front of the chip.

However, due to the poor adhesion and density of the prepared silicon nitride layer, it is not possible to cover the chip's electrode and light emitting area well. The strong acid solution penetrates the surface silicon nitride layer and the transparent conductive layer, which causes damage to the semiconductor epitaxial stack, and the appearance yield and photoelectric performance of the light emitting diode are affected. In addition, in the subsequent process of removing the silicon nitride layer with an acid solution and roughening the sidewall of the light emitting diode with an acid solution, impurities are adhered to the semiconductor epitaxial stack, especially the active layer, which may easily cause the IR leakage problem.

### SUMMARY

The disclosure aims to solve the problems of the background technology.

The disclosure provides a light emitting diode, which includes: a substrate having an upper surface and a lower surface opposite to each other; a semiconductor epitaxial stack including a first semiconductor layer, an active layer, and a second semiconductor layer stacked on the upper surface of the substrate; a transparent conductive layer disposed on an upper surface of the second semiconductor layer away from the substrate; and a sidewall formed on edges of the semiconductor epitaxial stack and the substrate.

The light emitting diode further includes a passivation layer covering a surface of the transparent conductive layer, the passivation layer is connected to the sidewall, a portion of the sidewall not covered by the passivation layer has a roughened structure, and the roughened structure includes a protrusion.

Preferably, the passivation layer at least wraps around an entire sidewall of the active layer.

Preferably, a portion of a sidewall of the first semiconductor layer covered by the passivation layer does not exceed one half of a thickness of the sidewall of the first semiconductor layer.

Preferably, a periphery of the semiconductor epitaxial stack forms a scribe line of the light emitting diode.

Preferably, a width of the scribe line ranges from 10 μm to 30 μm.

Preferably, the passivation layer includes one or more of SiOₓ, SiNₓ, MgF₂, TiOₓ, Ti₃O₅, and Al₂O₃.

Preferably, a thickness of the passivation layer is greater than 0.1 μm.

Preferably, the thickness of the passivation layer is less than 0.3 μm.

Preferably, the semiconductor epitaxial stack includes GaAs-based compound semiconductor material.

Preferably, the semiconductor epitaxial stack radiates infrared light.

Preferably, the substrate is a GaAs substrate.

The disclosure further provides a light emitting device, which adopts the light emitting diode provided by any of the above embodiments.

The disclosure further provides a manufacturing method for a light emitting diode, which includes steps as follows.

(1) A substrate is provided and a semiconductor epitaxial stack is grown on an upper surface of the substrate.

(2) A transparent conductive layer is disposed on an upper surface of the semiconductor epitaxial stack.

(3) A second electrode and a first electrode are disposed on the transparent conductive layer and under the substrate, respectively.

(4) Dry etching is performed starting from a surface of the transparent conductive layer to a first semiconductor layer of the semiconductor epitaxial stack so as to expose a surface of the first semiconductor layer to form a scribe line, and a passivation layer is evaporated to cover the transparent conductive layer, a portion of a sidewall, and a surface of the scribe line.

(5) The light emitting diode is cut into independent dies, the separated dies are placed in a solution for wet etching so as to obtain a light emitting diode with a sidewall having a roughened structure.

The beneficial technical effects brought about by the technical solution used in the disclosure include the following. The light emitting diode is provided with a passivation layer, which can prevent the etching liquid from etching and damaging the transparent conductive layer and the semiconductor epitaxial stack during the roughening process of the light emitting diode, thereby the appearance yield of the semiconductor light emitting diode is improved and the photoelectric performance of the light emitting diode is improved. At the same time, the IR leakage problem caused by impurities adhering to the active layer during the sidewall roughening process is avoided, thereby the reliability of the light emitting diode is improved.

### BRIEF DESCRIPTION OF THE DRAWINGS

FIG. 1 is a cross-sectional view of a light emitting diode before roughening in the related art.

FIG. 2 is a cross-sectional view of a light emitting diode after roughening in the related art.

FIG. 3 is a cross-sectional view of a light emitting diode described in Embodiment 1 of the disclosure.

FIG. 4 to FIG. 8 show steps for manufacturing a light emitting diode described in Embodiment 2 of the disclosure.

FIG. 9 is a cross-sectional view of a light emitting diode described in Embodiment 3 of the disclosure.

### DESCRIPTION OF THE EMBODIMENTS

The embodiments of the disclosure will be described in detail below with reference to the accompanying drawings and embodiments. Before describing the disclosure, it should be understood that the disclosure may be implemented in many different forms. Therefore, the disclosure is not limited to the specific embodiments described below.

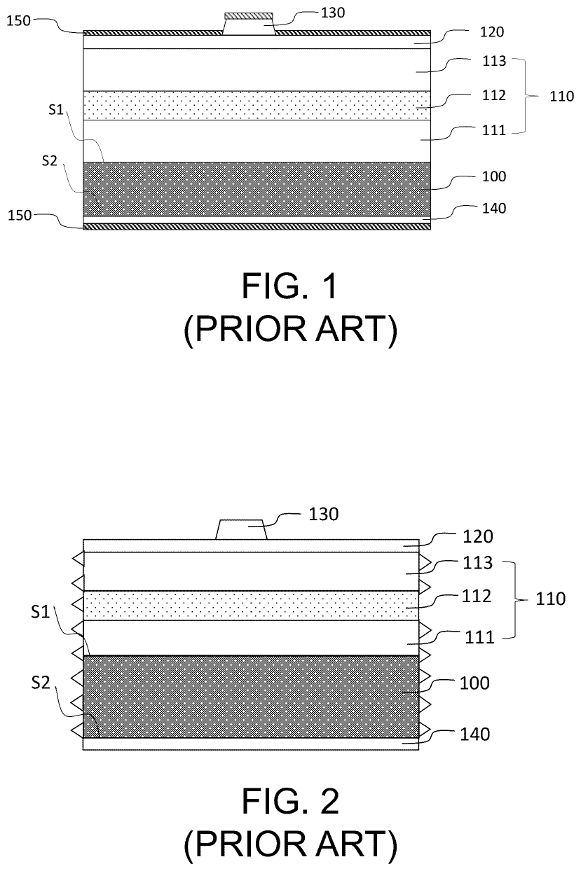

Referring to the cross-sectional view of a light emitting diode before roughening in the related art shown in FIG. 1, the light emitting diode includes a substrate 100, a semiconductor epitaxial stack 110, a transparent conductive layer 120, a second electrode 130, a first electrode 140, and a silicon nitride protective layer (or silicon nitride layer) 150. The substrate 100 includes an upper surface S1 and a lower surface S2, and the semiconductor epitaxial stack 110 includes a first semiconductor layer 111, an active layer 112, and a second semiconductor layer 113. The semiconductor epitaxial stack 110 radiates infrared light, and the transparent conductive layer 120 is disposed on the semiconductor epitaxial stack 110 to evenly diffuse the current. The second electrode 130 having the same polarity as the second semiconductor layer 113 is disposed on the upper surface of the transparent conductive layer 120. The first electrode 140 is disposed below the lower surface S2.

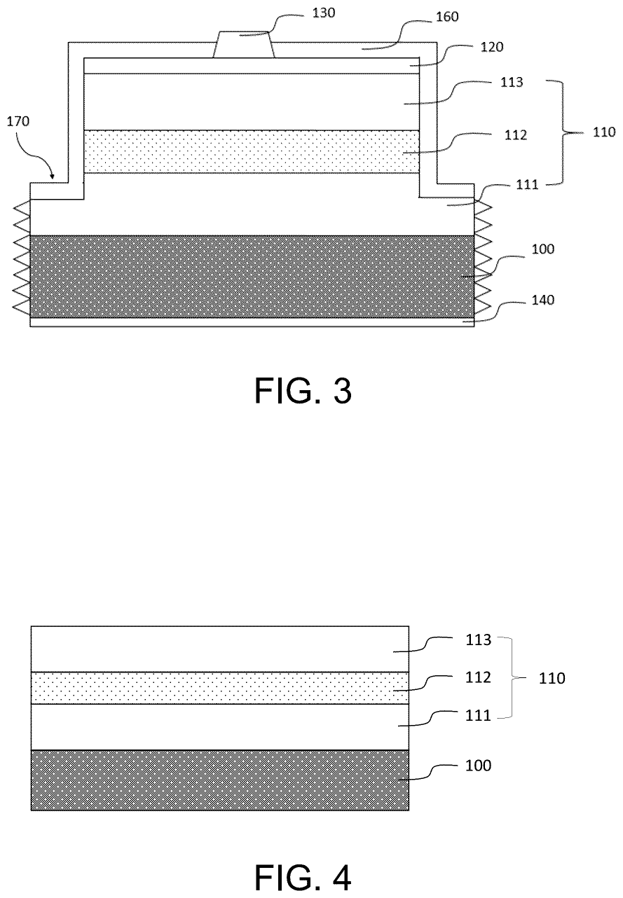

In order to increase the luminous brightness of the light emitting diode, the sidewall may be roughened, thereby the light extracting efficiency can be improved. See FIG. 2 for a cross-sectional view of the light emitting diode after roughening.

However, during the roughening process, the addition of acid solution damages the transparent conductive layer 120 and the electrode of the light emitting diode, thereby the reliability and luminous efficiency of the light emitting diode are affected. In the related art, in order to solve this problem, the silicon nitride layer 150 is deposited on the surface of the chip (or die) by plasma enhanced chemical vapor deposition (PECVD) to prevent the acid solution from damaging the transparent conductive layer 120 and the semiconductor epitaxial stack 110.

However, the silicon nitride layer 150 used in the related art has a problem of poor adhesion, which may cause the acid solution to penetrate the silicon nitride layer 150 and cause a certain degree of damage to the transparent conductive layer 120 and the semiconductor epitaxial stack 110. Furthermore, during the roughening process and the subsequent removal of the silicon nitride layer 150, impurities are generated. When the impurities are adhered to the active layer 112 in the semiconductor epitaxial stack 110, the IR leakage problem is likely to occur, thereby the reliability of the chip is affected.

In order to solve the defects of the related art, the disclosure provides a light emitting diode and a manufacturing method thereof.

### Embodiment 1

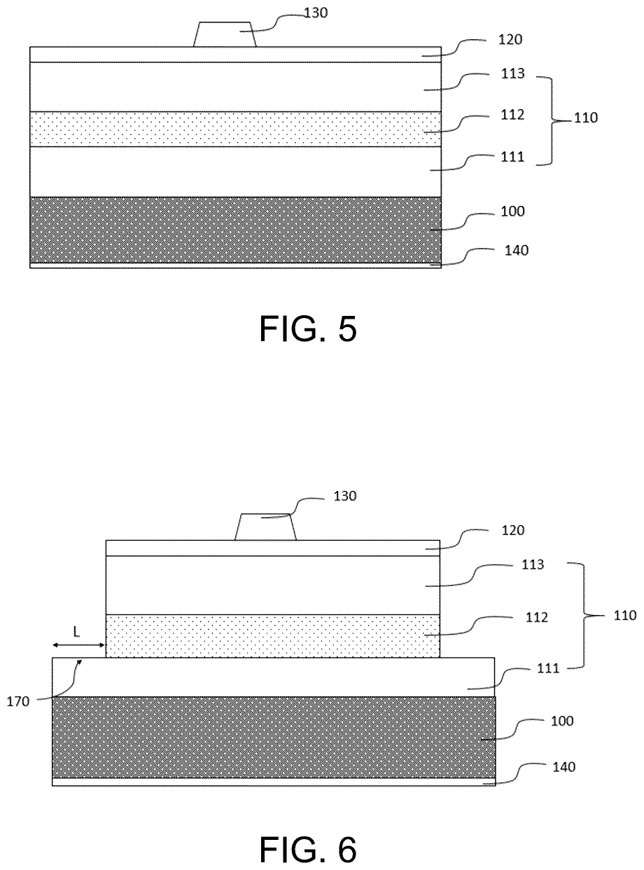

This embodiment provides a light emitting diode, a cross-sectional view thereof is shown in FIG. 3, and the light emitting diode includes: a substrate 100; a semiconductor epitaxial stack 110 including a first semiconductor layer 111, an active layer 112, and a second semiconductor layer 113; a transparent conductive layer 120; a second electrode 130; a first electrode 140; a passivation layer 160; and a scribe line 170.

The substrate 100, in this embodiment, uses a GaAs substrate, which does not absorb infrared light and can ensure the luminous brightness. However, in specific implementation, the substrate material is not limited to GaAs, and other materials may be selected according to different situations.

The thickness of the GaAs substrate 100 has an appropriate range depending on the size thereof. If the thickness of the GaAs substrate 100 is relatively thin, cracks are likely to occur during the manufacturing process of the semiconductor epitaxial stack 110. On the other hand, if the thickness of the GaAs substrate 100 is too thick, the material cost increases. Therefore, when the size of the GaAs substrate 100 is large, for example, when the diameter is 75 mm, in order to prevent cracking during the manufacturing process, the thickness of the GaAs substrate 100 is preferably 250 μm to 500 μm. Similarly, when the diameter is 50 mm, the thickness is preferably 200 μm to 400 μm, and when the diameter is 100 mm, the thickness is preferably 350 μm to 600 μm.

By increasing the thickness of the substrate according to the size of the GaAs substrate 100, warping of the semiconductor epitaxial stack 110 caused by the active layer 112 can be reduced. Since the temperature distribution during epitaxial growth becomes uniform, the uniformity of the wavelength distribution within the plane of the active layer 112 can be improved.

In order to reduce the propagation of defects in the GaAs substrate 100 and the semiconductor epitaxial stack 110 and improve the crystal quality of the semiconductor epitaxial stack 110, a buffer layer (not shown in the drawing) may be disposed between the GaAs substrate 100 and the semiconductor epitaxial stack 110. The material of the buffer layer is preferably the same as the substrate for epitaxial growth. Therefore, in this embodiment, the buffer layer is preferably made of the same material as the GaAs substrate 100. In order to reduce the propagation of defects, the buffer layer may also be a multilayer film made of a material different from the GaAs substrate 100. The thickness of the buffer layer is preferably 0.1 μm or more, more preferably 0.2 μm or more.

The semiconductor epitaxial stack 110 is obtained by MOCVD (metal organic chemical vapor deposition) or other growth methods, and is a semiconductor material that may provide conventional radiation such as ultraviolet, blue, green, yellow, red, infrared light. Specifically, the material may be a material providing radiation in the 200 nm to 950 nm band, such as common nitrides, specifically such as GaN-based semiconductor epitaxial stack. The GaN-based epitaxial stack is commonly doped with elements such as aluminum and indium, and mainly provide radiation in the 200 nm to 550 nm band; or the common AlGaInP-based or AlGaAs-based semiconductor epitaxial stack, which mainly provides radiation in the 550 nm to 950 nm band.

The first semiconductor layer 111 and the second semiconductor layer 113 may be respectively doped with n-type or p-type to provide at least electrons or holes, respectively. The n-type semiconductor layer may be doped with an n-type dopant such as Si, Ge, or Sn, and the p-type semiconductor layer may be doped with a p-type dopant such as Mg, Zn, Ca, Sr, Ba, or C. The first semiconductor layer 111, the active layer 112, and the second semiconductor layer 113 may be made of materials such as aluminum gallium indium nitride, gallium nitride, aluminum gallium nitride, aluminum indium phosphide, aluminum gallium indium phosphide, gallium arsenide, or aluminum gallium arsenide. The first semiconductor layer 111 or the second semiconductor layer 113 includes a cover layer for providing electrons or holes, and may include other layer materials such as a current spreading layer, a window layer, or an ohmic contact layer, which are arranged as different multilayers according to different doping concentrations or component contents. The active layer 112 is a region providing light radiation for the recombination of electrons and holes. Different materials may be selected according to different luminescent wavelengths. The active layer 112 may be a periodic structure of a single quantum well or multiple quantum wells. By adjusting the composition ratio of the semiconductor material in the active layer 112, it is expected that light of different wavelengths may be radiated.

In this embodiment, the semiconductor epitaxial stack 110 preferably includes a GaAs-based material. The semiconductor epitaxial stack 110 radiates infrared light. In this embodiment, the first semiconductor layer 111 is preferably made of AlGaAs material, and the active layer 112 is formed by alternately stacking well layers and barrier layers. The active layer 112 has 5 to 15 periods of InGaAs/AlGaAsP multiple quantum wells, the thickness of the InGaAs well layer in each period is 10 nm to 20 nm, and the thickness of the AlGaAsP barrier layer is 3 nm to 15 nm. The second semiconductor layer 113 is preferably made of AlGaAs material.

GaAs-based infrared light emitting diodes have a high transmittance in GaAs material due to the wavelength of the light emitted, which makes each side of the light emitting diode a light emitting surface. Therefore, the sidewall of the LED may usually be roughened to form a roughened structure with protrusions, thereby the light extracting efficiency of the sidewall of the LED is improved, and the luminous efficiency of the LED is improved. In this embodiment, the substrate 100 and the semiconductor epitaxial stack 110 are both GaAs-based materials, and the sidewall of the substrate 100 and a portion of the sidewall of the semiconductor epitaxial stack 110 have roughened structures.

The transparent conductive layer 120 is located over the semiconductor epitaxial stack 110 and is used to expand the current; in order to allow the light radiated by the semiconductor epitaxial stack 110 to be emitted, the light transmittance of the transparent conductive layer 120 is preferably greater than 70%, and more preferably greater than 90%. In this embodiment, the transparent conductive layer 120 is preferably ITO.

The second electrode 130 is disposed on a partial region of the surface of the transparent conductive layer 120. In some embodiments, the second electrode 130 includes a pad electrode and an extended electrode, wherein the pad electrode is mainly used for external wiring during packaging. The pad electrode may be designed into different shapes according to the actual wiring needs, such as cylindrical, square, or other polygonal shapes. The extended electrode may be formed in a predetermined pattern shape, and the extended electrode may have various shapes, specifically, such as a stripe shape, which may facilitate current expansion.

The light emitting diode further includes the first electrode 140. In this embodiment, the first electrode 140 is formed on the back side of the substrate 100 in a manner of the whole surface. The substrate 100 of this embodiment is a conductive substrate, the second electrode 130 and the first electrode 140 are formed on opposite sides of the substrate 100, so that the current vertically flows through the semiconductor epitaxial stack, which provides uniform current density, and the photoelectric conversion efficiency of the light emitting diode is improved.

The second electrode 130 and the first electrode 140 are preferably made of a metal material, and the metal material is preferably one or more of Au, Ge, Ni, Cr, Al, Cu, Ti, Pt, and Zn.

In order to prevent the sidewall and surface of the chip from being damaged during roughening and to prevent the IR leakage problem caused by the impurities generated by the sidewall roughening adhering to the semiconductor epitaxial stack, especially the active layer, the embodiment of the disclosure provides the passivation layer 160.

The scribe line 170 is formed by etching from the transparent conductive layer 120 toward the first semiconductor layer 111. The scribe line 170 is used for subsequent cutting of the light emitting diode to obtain independent dies. The scribe line 170 exposes the sidewall of the semiconductor epitaxial stack 110. The sidewall, the surface of the scribe line 170, and the surface of the transparent conductive layer 120 simultaneously form the passivation layer 160 to protect the sidewall and the exposed surface of the semiconductor epitaxial stack 110. The width of the scribe line 170 is from 10 μm to 30 μm, and the width can ensure the attaching property of the passivation layer 160, so as to prevent the passivation layer 160 from being damaged or destroyed during subsequent cutting.

Preferably, the material of the passivation layer 160 is an insulating inert material, such as one or a combination of SiOₓ, SiNₓ, MgF₂, TiOₓ, Ti₃O₅, and Al₂O₃, the passivation layer 160 may be formed by evaporation, chemical deposition, atomic force deposition, thereby the thickness and uniformity of the passivation layer 160 is ensured. In this embodiment, magnesium fluoride is used as the material of the passivation layer 160, and the passivation layer 160 is attached to the surface and sidewall of the light emitting diode by evaporation. In this embodiment, the passivation layer 160 is preferably made of magnesium fluoride material.

As shown in FIG. 3, the passivation layer 160 covers the transparent conductive layer 120 and exposes the second electrode 130. This is to prevent the problem of uneven current expansion caused by the transparent conductive layer 120 being damaged during the roughening process. Moreover, compared with the silicon nitride layer used in the related art, the magnesium fluoride material has stronger adhesion and covers the transparent conductive layer 120 more tightly, so that the acid solution cannot easily pass through the passivation layer 160 through the gaps, thereby the appearance yield and light emitting efficiency of the light emitting diode being affected by the damage of the transparent conductive layer 120 and the semiconductor epitaxial stack 110 can be prevented.

Furthermore, the passivation layer 160 is connected to the sidewall and at least extends to cover the entire sidewall portion of the active layer 112. In the related art (such as FIG. 1), when the light emitting diode is being roughened, impurities may adhere to the sidewalls of the semiconductor epitaxial stack 110 or even the sidewall of the active layer 112, thereby the IR leakage problem of the light emitting diode is caused, the reliability of the chip is affected, and the luminous efficiency of the chip is also affected. After the active layer 112 is completely covered by the passivation layer 160, the IR leakage problem can be solved. Meanwhile, the damage to the active layer 112 and reduction in the luminous brightness that are caused by etching of the active layer 112 by the acid solution can be prevented.

The luminous brightness of the light emitting diode is closely related to the roughened area. Preferably, the portion of the sidewall of the first semiconductor layer 111 wrapped by the passivation layer 160 does not exceed one half of the sidewall of the first semiconductor layer 111. If the passivation layer 160 covers too much of the sidewall, for example, more than half of the sidewall of the first semiconductor layer 111, then the roughened sidewall portion of the light emitting diode is reduced, and the light extracting efficiency is reduced, which causes insufficient luminous brightness of the chip. In this embodiment, the entire sidewall of the substrate 100 and more than two-thirds of the sidewall of the first semiconductor layer 111 have roughened structures, thereby the luminous brightness of the chip is ensured.

The reliability and the luminous brightness of the light emitting diode are closely related to the thickness of the passivation layer 160. Preferably, the thickness of the passivation layer 160 is preferably 100 nm to 300 nm. If the thickness of the passivation layer 160 is too thin, for example, less than 100 nm, then the layer cannot effectively prevent the etching solution from etching the semiconductor epitaxial stack 110 during the roughening process. At the same time, in order to ensure the light extracting efficiency, the thickness of the passivation layer 160 should not be too thick, for example, higher than 300 nm. Therefore, the thickness of the passivation layer 160 is preferably greater than or equal to 100 nm and less than or equal to 300 nm. In this embodiment, the thickness range of the passivation layer 160 is 150 nm to 250 nm.

In the disclosure, by disposing the passivation layer 160, it is possible to prevent the etching solution from damaging the transparent conductive layer 120 and the semiconductor epitaxial stack 110 during the sidewall roughening process, and also prevent the impurities in the roughening process from adhering to the active layer 112, which improves the appearance yield of the light emitting diode and improves the luminous efficiency of the light emitting diode. At the same time, the IR leakage problem of the light emitting diode is alleviated, thereby the reliability of the chip is improved.

### Embodiment 2

The manufacturing process of the light emitting diode of Embodiment 1 is described in detail below.

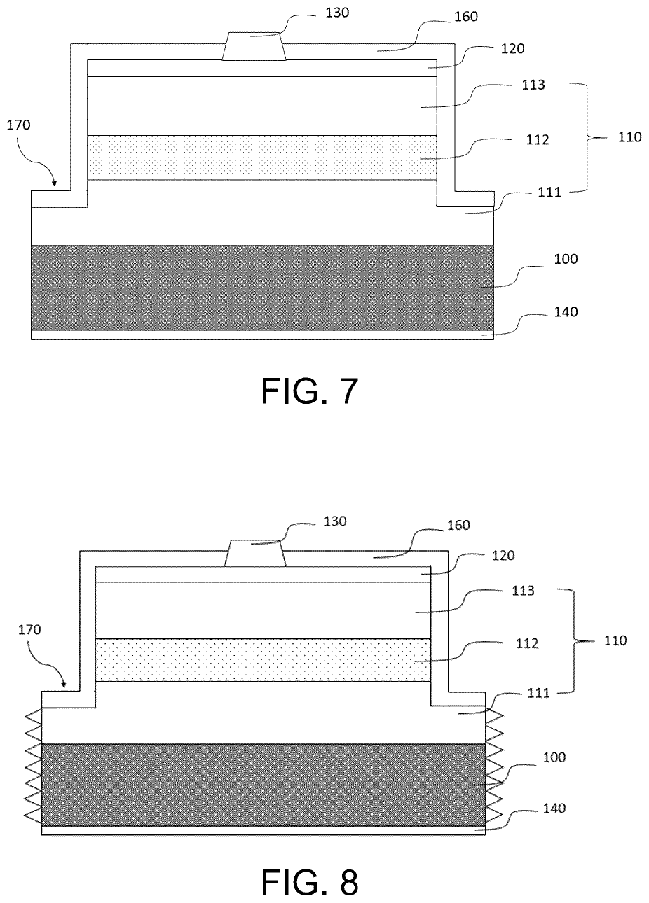

First, as shown in FIG. 4, the substrate 100 is provided, the substrate has an upper surface and a lower surface opposite to each other; the substrate is preferably a GaAs substrate; the first semiconductor layer 111, the active layer 112, and the second semiconductor layer 113 are sequentially formed on the substrate 100 from bottom to top. Specifically, a MOCVD (Metal Organic Chemical Vapor Deposition) process is generally used to sequentially grow the semiconductor epitaxial stack 110.

Then, as shown in FIG. 5, the transparent conductive layer 120 is disposed on the upper surface of the semiconductor epitaxial stack 110 away from the substrate. In this embodiment, the material of the transparent conductive layer 120 is preferably ITO. The second electrode 130 is evaporated on the upper surface of the transparent conductive layer 120. In this embodiment, the material of the second electrode 130 is Cr, Ti, Pt, or Au. The first electrode 140 is evaporated on the lower surface of the substrate 100. In this embodiment, the material of the first electrode 140 is Au and Ge.

Then, as shown in FIG. 6, dry etching is performed on the light emitting diode, starting from the transparent conductive layer 120, etching at least the active layer 112, exposing the surface of the first semiconductor layer 111, and forming the scribe line 170. A width L of the scribe line is from 10 μm to 30 μm, which is convenient for subsequent cutting to form dies.

Thereafter, as shown in FIG. 7, the passivation layer 160 is evaporated on the surface of the transparent conductive layer 120 and the sidewall of the semiconductor epitaxial stack 110, and the passivation layer 160 at least completely wraps the active layer 112. In this embodiment, magnesium fluoride is used as the material of the passivation layer 160. As an inert material, magnesium fluoride is not easily etched by the acid solution used for roughening, and can effectively protect the sidewalls of the transparent conductive layer 120 and the active layer 112 of the light emitting diode. In this embodiment, the thickness of magnesium fluoride is 200 nm.

Next, as shown in FIG. 8, the wafer is cut into independent dies, and the dies are transferred to a supporting substrate (not shown in the drawing), and then the sidewalls of the dies are roughened using an acidic solution, preferably, in this embodiment, a nitric acid solution. Specifically, the dies are placed in the nitric acid solution and roughened for 3 s to 200 s (3 seconds to 200 seconds). The portion of the sidewall covered by the passivation layer 160 has no roughened structure, while the portion of the sidewall not covered by the passivation layer, that is, the portion of the sidewall of the first semiconductor layer 111 and the sidewall of the substrate 100, form roughened structures. In addition, the surfaces of the transparent conductive layer 120 and the scribe line 170 are deposited with the passivation layer 160, and thus are not etched. After the sidewall is roughened, a light emitting diode structure as shown in FIG. 8 is obtained.

The disclosure adopts wet etching to etch the sidewall of the light emitting diode in one step to obtain a sidewall roughened structure, which can improve the light output brightness of the light emitting diode. At the same time, the manufacturing process can effectively protect the transparent conductive layer 120 of the light emitting diode, the surface of the semiconductor epitaxial stack 110, and the sidewall of the active layer 112 from being etched and damaged by the etching solution or from being adhered by impurities, thereby the appearance quality and luminous efficiency of the light emitting diode are guaranteed, and the influence of IR leakage is eliminated.

### Embodiment 3

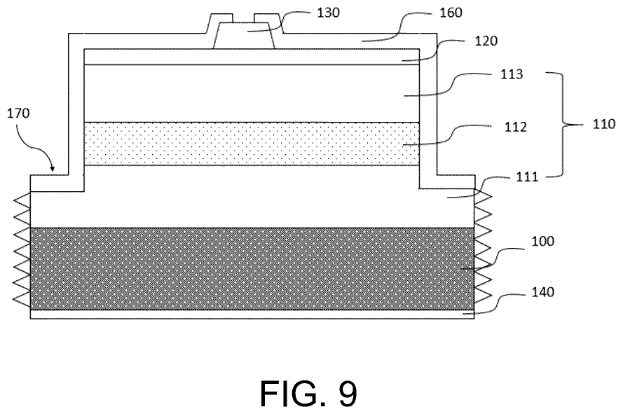

This embodiment provides a light emitting diode, and a cross-sectional view thereof is shown in FIG. 9.

The difference from the Embodiment 1 shown in FIG. 3 is that in Embodiment 3, the passivation layer 160 further covers the side surface and a part of the surface of the second electrode 130. During the roughening process, the acid solution can be better blocked from entering the transparent conductive layer or epitaxial stack, thereby a better protection effect is provided.

### Example 4

The semiconductor light emitting diode provided by the disclosure may be widely used in fields, for example, security monitoring, distance measurement, remote control, infrared reception, and infrared sensing.

Specifically, a light emitting device is provided in this embodiment. A light emitting unit in the light emitting device may be the light emitting diode provided in Embodiment 1, Embodiment 3, or both Embodiment 1 and Embodiment 3, or may be a combination of two light emitting diodes provided in Embodiment 1 and Embodiment 3.

What is claimed is:

1. A light emitting diode, comprising:
a substrate having an upper surface and a lower surface opposite to each other;
a semiconductor epitaxial stack comprising a first semiconductor layer, an active layer, and a second semiconductor layer stacked on the upper surface of the substrate;
a transparent conductive layer disposed on an upper surface of the second semiconductor layer away from the substrate;
a sidewall formed on edges of the semiconductor epitaxial stack and the substrate; and
a passivation layer covering a surface of the transparent conductive layer, wherein the passivation layer is connected to the sidewall, a portion of the sidewall not covered by the passivation layer has a roughened structure, and the roughened structure includes a protrusion.

2. The light emitting diode according to claim 1, wherein
the passivation layer at least wraps around an entire sidewall of the active layer.

3. The light emitting diode according to claim 1, wherein
a portion of a sidewall of the first semiconductor layer covered by the passivation layer does not exceed one half of a thickness of the sidewall of the first semiconductor layer.

4. The light emitting diode according to claim 1, wherein
a periphery of the semiconductor epitaxial stack forms a scribe line of the light emitting diode.

5. The light emitting diode according to claim 4, wherein
a width of the scribe line ranges from 10 μm to 30 μm.

6. The light emitting diode according to claim 1, wherein
the passivation layer comprises one or more of SiOₓ, SiNₓ, MgF₂, TiOₓ, Ti₃O₅, and Al₂O₃.

7. The light emitting diode according to claim 1, wherein
a thickness of the passivation layer is greater than 0.1 μm and less than 0.3 μm.

8. The light emitting diode according to claim 1, wherein
the semiconductor epitaxial stack comprises a GaAs-based compound semiconductor material.

9. The light emitting diode according to claim 1, wherein
the semiconductor epitaxial stack radiates infrared light.

10. The light emitting diode according to claim 1, wherein
the substrate is a GaAs substrate.

11. A light emitting device, comprising:
the light emitting diode according to claim 1.

12. A manufacturing method for a light emitting diode, comprising:
providing a substrate, and growing a semiconductor epitaxial stack on an upper surface of the substrate;
disposing a transparent conductive layer on an upper surface of the semiconductor epitaxial stack;
disposing a second electrode and a first electrode on the transparent conductive layer and under the substrate, respectively;
performing dry etching starting from a surface of the transparent conductive layer to a first semiconductor layer of the semiconductor epitaxial stack so as to expose a surface of the first semiconductor layer to form a scribe line, and evaporating a passivation layer to cover the transparent conductive layer, a portion of a sidewall, and a surface of the scribe line;
cutting the light emitting diode into independent dies, and placing the separated dies in a solution for wet etching so as to obtain a light emitting diode with a sidewall having a roughened structure.
